(19) United States
(12) Patent Application Publication
(10) Pub. No.: US 2008/0157225 A1
(43) Pub. Date: Jul. 3, 2008

(54) SRAM and logic transistors with variable height multi-gate transistor architecture

(76) Inventors: Suman Datta, Beaverton, OR (US); Brian S. Doyle, Portland, OR (US); Jack T. Kavalieros, Portland, OR (US); Yih Wang, Portland, OR (US)

Correspondence Address: INTEL/BLAKELY, 1279 OAKMEAD PARKWAY, SUNNYVALE, CA, 94085-4040, US

(21) Appl. No.: 11/648,521

(22) Filed: Dec. 29, 2006

(51) Int. Cl. H01L 21/336; H01L 29/768

(52) U.S. Cl. 257/401; 438/283; 257/E29.229; 257/E21.409

(57) ABSTRACT

Multi-gate transistors having different channel widths formed on non-planar semiconductor bodies have different sidewall heights and method of manufacturing the same. In an embodiment, a multi-gate SRAM transistor is formed on a non-planar semiconductor body having a greater sidewall height than a non-planar semiconductor body utilized for a multi-gate logic transistor to improve performance of SRAM and logic transistors formed on the same substrate. In another embodiment, to reduce cell area, a first SRAM transistor is formed on a non-planar semiconductor body having a greater sidewall height than a non-planar semiconductor body utilized for a second multi-gate SRAM transistor.

### BACKGROUND OF THE INVENTION

1. Field of the Invention

The present invention relates to the field of semiconductor integrated circuit manufacturing, and more particularly to multi-gate static random access memory (SRAM) transistors and multi-gate logic transistors having variable channel widths.

2. Discussion of Related Art

Multi-gate transistors have been under development to address the short channel effect (SCE) afflicting planar nano-scale transistors. A multi-gate transistor is a transistor where the gate electrode couples to the channel through more than one surface plane of the semiconductor, typically through sidewall portions formed by the non-planarity. Transistor 150, as shown in FIG. 1A, is such a non-planar device. A semiconductor body, having opposite sidewalls 106 and 107, and a top surface 108, is formed over a substrate comprised of isolation 103 on a handling substrate 102. The top surface 108 and the opposite sidewalls 106 and 107 are apportioned into a source 116, and a drain 117, and a channel covered by a gate insulator 112 and a gate electrode 113. In this transistor design, the device can be gated by the opposite sidewalls 106 and 107, as well as the top surface 108 of the device, reducing the SCE. Because the channel is gated by multiple gate electrode-semiconductor interfaces, the transistor having a non-planar channel is frequently called a multi-gate device.

Multi-gate, devices have been typically been formed having a fixed semiconductor body, or fin, sidewall height. For this reason, circuit designers are limited to a fundamental width and multiples of that width for all multi-gate transistors of a circuit formed on the substrate. As shown in FIG. 1B, multiple non-planar semiconductor bodies, each having a source 116 and drain 117 region are coupled by a common gate electrode 113 through a gate insulator 112 in an electrically parallel fashion on substrate 102 to form device 175. Device 175 limits circuit design flexibility because the current carrying width must be incremented discretely, not continuously. Also, because of lithographic pitch limitations, non-planar transistors like device 175 shown in FIG. 1B may incur a layout penalty relative to traditional single-gate transistors which can have their planar gate width scaled continuously.

### BRIEF DESCRIPTION OF THE DRAWINGS

FIGS. 1A and 1B are illustrations of perspective views of a conventional multi-gate transistor on a silicon-on-insulator (SOI) substrate and a conventional double fin multi-gate transistor on an SOI substrate, respectively.

FIG. 2A is a cross-sectional view of a first non-planar semiconductor body having a greater height than a second non-planar semiconductor body on a substrate in accordance with the present invention.

FIG. 2B is a perspective view of a continuous semiconductor body forming a first multi-gate transistor having a greater channel width than a second multi-gate transistor in accordance with the present invention.

FIG. 3 is a schematic of a six transistor SRAM cell in accordance with an embodiment of the present invention.

FIG. 4 is a plan view of a portion of an SRAM layout employing multi-gate transistors having non-planar semiconductor bodies with different sidewall heights in accordance with an embodiment of the present invention.

FIG. 5 is a cross-sectional view of a non-planar semiconductor body having a first height and first width for a multi-gate SRAM transistor with a first channel width and a non-semiconductor planar semiconductor body having a second height and a second width for a multi-gate logic transistor with a second channel width.

FIGS. 6A-6F are cross-sectional views of multi-gate transistors at various stages of fabrication in accordance with an embodiment of the present invention.

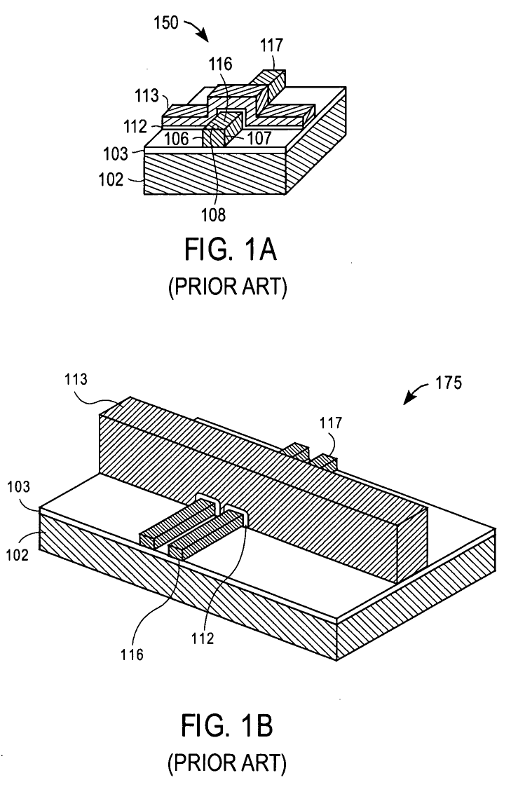

### DETAILED DESCRIPTION OF THE PRESENT INVENTION

In various embodiments, multi-gate transistor architectures for SRAM and logic transistors on a single substrate are described with reference to figures. However, certain embodiments may be practiced without one or more of these specific details, or in combination with other known methods and materials. In the following description, numerous specific details are set forth, such as specific materials, dimensions and processes, etc., in order to provide a thorough understanding of the present invention. In other instances, well-known semiconductor processes and manufacturing techniques have not been described in particular detail in order to not unnecessarily obscure the present invention. Reference throughout this specification to “an embodiment” means that a particular feature, structure, material, or characteristic described in connection with the embodiment is included in at least one embodiment of the invention. Thus, the appearances of the phrase “in an embodiment” in various places throughout this specification are not necessarily referring to the same embodiment of the invention. Furthermore, the particular features, structures, materials, or characteristics may be combined in any suitable manner in one or more embodiments.

Embodiments of the present invention include a first multi-gate transistor having a first channel width and a second multi-gate transistor having a second channel width, wherein at least one of the multi-gate transistors is in a static random access memory (SRAM) cell. As discussed below, the channel width of a multi-gate SRAM transistor is varied by changing either or both of a sidewall height and a top surface width of a non-planar semiconductor body to reduce the SRAM cell area and improve performance of SRAM and logic transistors formed on the same substrate.

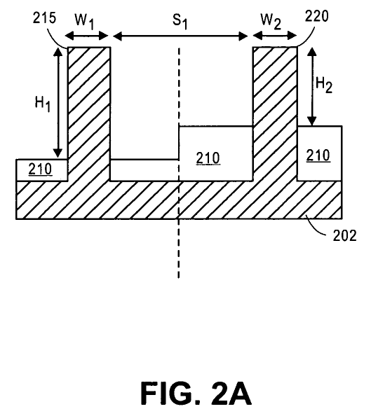

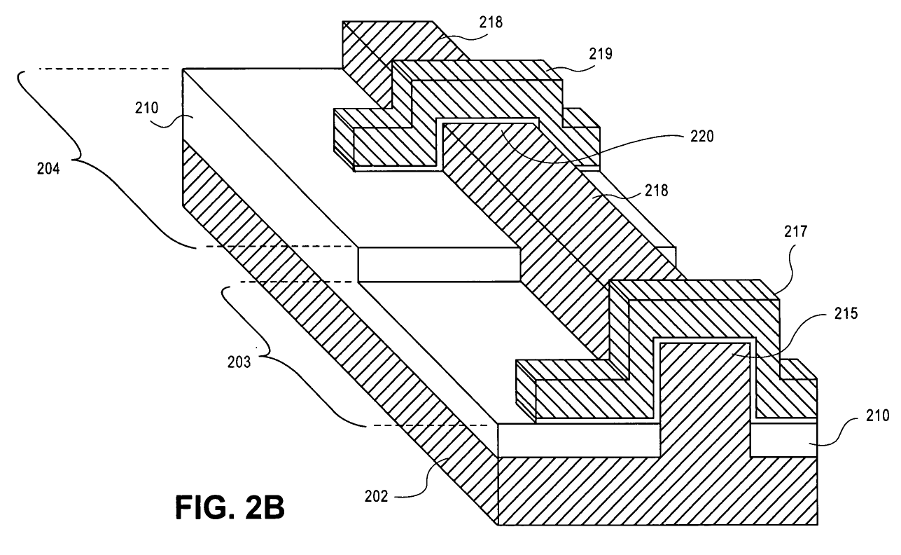

In one embodiment, shown in FIG. 2A, non-planar semiconductor bodies 215 and 220 are formed on a “bulk semiconductor” substrate 202, such as, but not limited to, a monocrystalline silicon substrate or a gallium arsenide substrate. In a further embodiment, the substrate 202 is a bulk silicon semiconductor having a doped epitaxial silicon layer with either p-type or n-type conductivity at an impurity concentration level between 1×10¹⁶-1×10¹⁹ atoms/cm³. In another embodiment, substrate 202 is a bulk silicon semiconductor substrate having an undoped, or intrinsic epitaxial silicon layer. In a “bulk semiconductor” substrate, unlike a silicon-on-insulator (SOI) substrate, there is no “buried” insulating layer between semiconductor portion used to fabricate the active devices and the semiconductor portion used for handling.

As shown in FIG. 2A, non-planar semiconductor bodies 215 and 220 on the bulk semiconductor substrate 202 are separated by isolation 210 and each body defines an individual multi-gate transistor channel width. For simplicity, non-planar semiconductor bodies 215 and 220 are referred to as “on” the substrate, wherein the substrate is the semiconductor portion below the top surface of isolation 210. However, non-planar semiconductor bodies 215 and 220 could also be considered “in” the substrate if a different reference plane is chosen. As shown, non-planar semiconductor body 215 has a top surface with a width W, and two sidewalls extending by a height H₁ above the top surface of the adjacent isolation 210. Similarly, non-planar semiconductor body 220 has a top surface with a width W, and two sidewalls extending by a height H₂ above the top surface of the adjacent isolation 210. In a particular embodiment, both the top surface and the sidewalls of non-planar semiconductor 215 and 220 become “gated surfaces” of a multi-gate transistor when a gate stack including a gate insulator and gate electrode is subsequently formed over a portion of the non-planar semiconductor bodies (not shown) such that both the top surface and two sidewalls of each fin channel contribute to the total effective channel width of the non-planar transistors. One such embodiment is typically referred to as a “tri-gate” transistor. A first tri-gate transistor has a channel width Z₁ defined for the non-planar semiconductor body 215 as 2(H₁)+W. A second tri-gate transistor has a channel width Z₂ further defined for the non-planar semiconductor body 220 as 2(H₂)+W.

In an embodiment, the sidewall height of the semiconductor bodies 215 and 220 are varied to provide two transistors having different channel widths while the substrate area occupied by each transistor remains constant. As shown in FIG. 2A, because first non-planar semiconductor body 215 has a width W and a sidewall height H₁, while a second non-planar semiconductor body 220 has a width W and a sidewall height H₂, that is less than sidewall height H₁, channel width Z₁ of a first tri-gate transistor is greater than channel width Z₂ of a second tri-gate transistor. Because semiconductor bodies 215 and 220 have the same width W, the substrate surface area occupied by each body can remain nearly constant.

As indicated by the dashed line in FIG. 2A, non-planar semiconductor body 215 and non-planar semiconductor body 220 may be positioned relative to each other on substrate 202 in a variety of ways. In one embodiment, non-planar semiconductor body 215 is discontinuous with non-planar semiconductor 220 and separated by a distance S₁, as shown. In another embodiment, as shown in FIG. 2B, non-planar semiconductor body 215 having a first sidewall height is adjacent to non-planar semiconductor body 220 having a second sidewall height to form a plurality of multi-gate transistors having different channel width in a single continuous non-planar semiconductor body.

Referring to FIG. 2B, multi-gate transistors 203 and 204 include non-planar semiconductor bodies 215 and 220, respectively, extending up from substrate 202 above isolation 210. A first gate stack 217, having a gate dielectric and gate electrode, extends over non-planar semiconductor body 215. A second gate stack 219, including a gate dielectric and gate electrode, extends over non-planar semiconductor body 220. Completing the multi-gate transistors 203 and 204 are source/drain regions 218 on opposite sides of gate stacks 217 and 219, respectively. In the particular embodiment shown in FIG. 2B, a source/drain region 218 is formed in a portion of both non-planar semiconductor body 215 and non-planar semiconductor body 220, tying a first and second multi-gate transistor together. Thus, a continuous non-planar semiconductor body having a plurality of sidewall heights forms a plurality of multi-gate transistors with different channel widths.

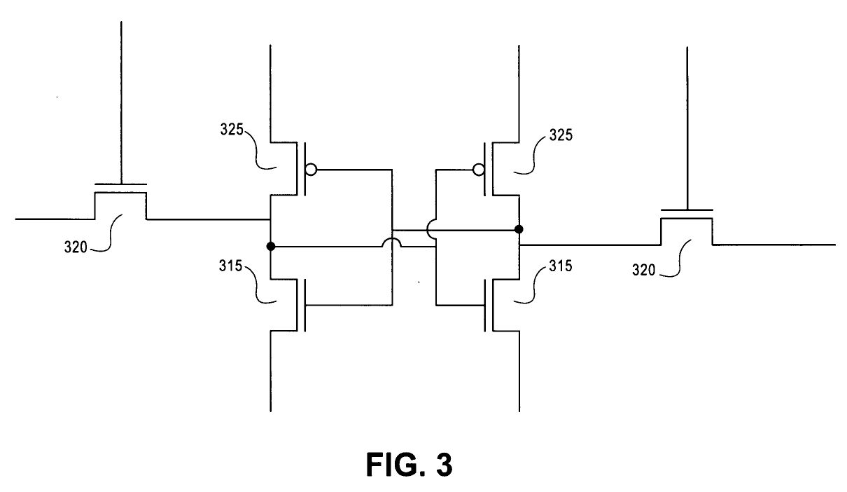

In an embodiment, a first multi-gate transistor having a first non-planar semiconductor body sidewall height and a second multi-gate transistor having a second non-planar semiconductor body sidewall height are both SRAM transistors in an SRAM cell. A schematic of a 6 transistor (6T) SRAM cell is shown in FIG. 3. As shown, a 6T SRAM cell includes pull-down transistors 315, access transistors 320 and pull-up transistors 325. In particular embodiments, the sidewall height of the non-planar semiconductor body of the pull-down transistor 315 is significantly greater than the sidewall height of the non-planar semiconductor body of the pass transistor 320 to increase the static noise margin of the SRAM cell. In SRAM bitcell design, one important criterion is called the beta (β) ratio. The beta ratio of a memory cell is the gate width/length (W/L) ratio of the pull-down transistor to the gate W/L ratio of the access transistor. The β ratio (or simply β) has an effect on access speed and on cell stability. In general, for a given cell size, a higher beta ratio improves cell stability. In an embodiment, a significantly greater sidewall height of the semiconductor body of pull-down transistor 315 causes pull-down transistor 315 to have a significantly greater channel width than that of pass transistor 320, thereby increasing β. In a certain embodiment, the sidewall height of the non-planar semiconductor body of pull-down transistor 315 is greater than the sidewall height of the non-planar semiconductor body of pass transistor 320 so that the ratio of the pull-down transistor 315 channel width to the pass transistor 320 channel width is 1.5:1 to achieve a high β of 1.5. In one such embodiment, pull-down transistor 315 and pass transistor 320 are each tri-gate transistors and pull-down transistor 315 has a sidewall height at least 25% greater than the sidewall height of pass transistor 320 while semiconductor body width is held constant. In an alternate embodiment, the sidewall height of the non-planar semiconductor body of pull-down transistor 315 is greater than the sidewall height of the non-planar semiconductor body of pass transistor 320 so that the ratio of the pull-down transistor 315 channel width to the pass transistor 320 channel width has a ratio of 2:1 to achieve a high β of 2.

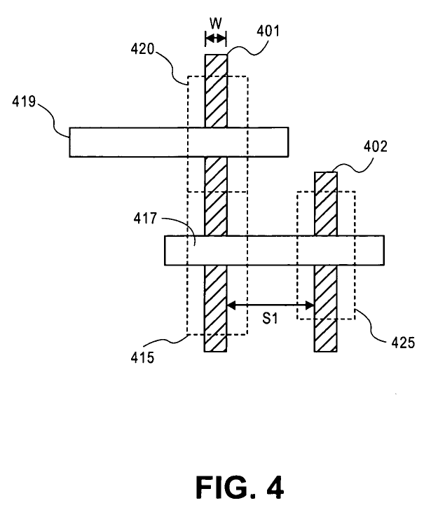

An embodiment of an SRAM layout employing a pull-down transistor formed on a semiconductor body having a greater sidewall height than that of a pass transistor is depicted in a layout view in FIG. 4. Dashed lines represent pull-down transistor 415, pass transistor 420 and pull-up transistor 425. Non-planar semiconductor bodies 401 and 402 are gated with gate stacks 417 and 419. As shown, non-planar semiconductor body 401 extends continuously between pull-down transistor 415 and pass transistor 420. Similarly, gate stack 417 extends continuously between the non-planar semiconductor body 401 of pull-down transistor 415 and non-planar semiconductor body 402 of the pull-up transistor. In a particular embodiment, continuous non-planar semiconductor body 401 having a single width W has a first region with a first sidewall height forming pull-down transistor 415 and a second region with a second sidewall height forming pass transistor 420. As was shown in FIG. 2B, the continuous non-planar semiconductor body having a plurality of sidewall heights enables multi-gate transistors to have a plurality of channel widths (Z). As shown in FIG. 4, no layout penalty is incurred by the greater channel width (Z) of pull-down transistor 415 because continuous non-planar semiconductor body 401 has a single width W for both the pull-down transistor 415 and pass transistor 420. Therefore, the SRAM cell area is reduced for a given β ratio. As shown, non-planar semiconductor body 401 is spaced apart from non-planar semiconductor body 402 a distance S₁. In a particular embodiment, S1 is the minimum lithographically definable space. Because the sidewall height of the non-planar semiconductor body 401 in the region of pull-down transistor 415 is greater than that in the region of pass transistor 420, a second non-planar semiconductor body need not be tied in parallel (thereby increasing the distance S1) to form pull-down transistor 415 in the high β SRAM cell layout of FIG. 4. Because, as previously discussed in reference to FIGS. 2A and 2B, the channel width of a non-planar transistor can be increased via extending the sidewall height of the non-planar semiconductor body, there is essentially no layout penalty incurred in the SRAM cell when the channel width of the pull-down transistor 415 to pass transistor 420 has a ratio greater than 1:1 in order to achieve a high β.

In a further embodiment, the continuous non-planar semiconductor body 401 can further have a plurality of widths W to allow for pull-down transistor 415 to have different subthreshold characteristics than pass transistor 420. Depending on the geometry and doping of non-planar semiconductor body 401, subthreshold characteristics of multi-gate transistors 415 and 420 can depend strongly on the contribution of the top surface of non-planar semiconductor body 401 to channel conduction.

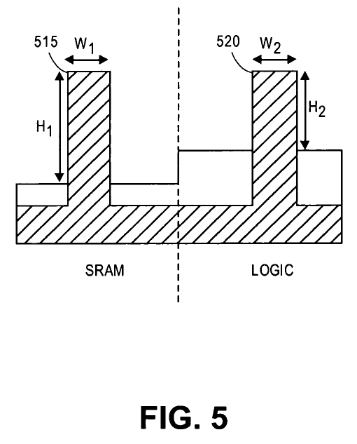

In another embodiment, at least one of the width WI and sidewall height H₁ is greater for a multi-gate SRAM transistor than for a multi-gate logic transistor. As shown in FIG. 5, a first multi-gate transistor having a non-planar semiconductor body 515 with sidewall height H₁ and width W₁ is fabricated in one region of a substrate while a second multi-gate transistor having a non-planar semiconductor body 520 with sidewall height H₂ and width W₂ is fabricated in another region of the same substrate. In one such embodiment, non-planar semiconductor body 515 is employed in a multi-gate SRAM transistor while non-planar semiconductor body 520 is employed in a multi-gate logic transistor. In a particular embodiment, W₁+2H₁ is 1.5 times greater than W₂+2H₂ such that the multi-gate SRAM transistor has a channel width 1.5 times greater than that of the multi-gate logic transistor when W₁ is equal to W₂.
In a further embodiment, as shown in FIG. 5, non-planar semiconductor body 515 for the SRAM transistor has a sidewall height H₁ that is greater than sidewall height H₂ of non-planar semiconductor body 520 for the logic transistor. In a particular embodiment, non-planar semiconductor body 515 has a sidewall height H₁ between 50% and 100% greater than the sidewall height H₂. For example, in a 45 nm lithography node, W₁ is 35 nm and H₁ is 120 nm while W₂ is 35 nm and H₂ is 60 nm. In such embodiments, the advantages of highly non-planar transistors having a sidewall height H₂ can be realized in one area (SRAM) of a device independently from a second area (logic) of the same device. The relatively smaller sidewall height H₁ of the logic transistor decreases the frequency and size of snap errors that can occur when adapting multi-gate transistors to an existing design database originally developed for planar, single-gate devices. For example, logic inverter sizing must be mapped from the continuous sizing scheme available in planar, single-gate technology to the quantized sizing of non-planar, multi-gate technology. If such a mapping process results in too large of an error (e.g. 10% root mean square (RMS) in channel width Z) between the channel width of a designed single-gate transistor and the size of a mapped multi-gate transistor, power and performance issues can result. However, there is typically no such design library limitation on SRAM cells and therefore the sidewall height of the non-planar semiconductor body 515 need only be limited by the fabrication process (e.g. aspect ratios, etc.). Thus, in an embodiment, a semiconductor body having the relatively larger sidewall height H₁ is fabricated for an SRAM transistor on the same substrate as a logic transistor having the relatively smaller sidewall height H₂ to improve SRAM cell read current and increase SRAM array efficiency (i.e. greater number of bit cells tied to the bit-line) while also reducing the multi-gate transistor design issues relating primarily to logic transistors.

In an alternate embodiment, non-planar semiconductor body 515 for the SRAM transistor has a width W₁ that is greater the width W₂ of non-planar semiconductor body 520 for the logic transistor. In a particular embodiment, W₁ is between 20% and 35% greater than W₂. For example, for a 45 nm lithography node, W₁ may be between 7 nm and 12 nm greater than a 35 nm W₂. Because width W₂ is relatively smaller, the subthreshold slope of the logic transistor will be relatively less than for the SRAM transistor. Thus, subthreshold slope of a logic transistor in a microprocessor may be tuned independently from that of an SRAM transistor in an SRAM cell of the microprocessor.

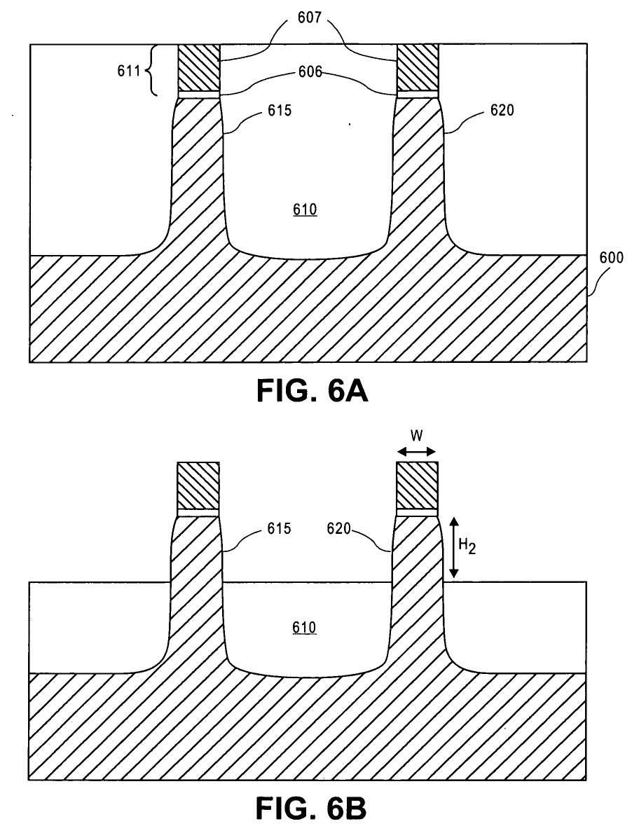

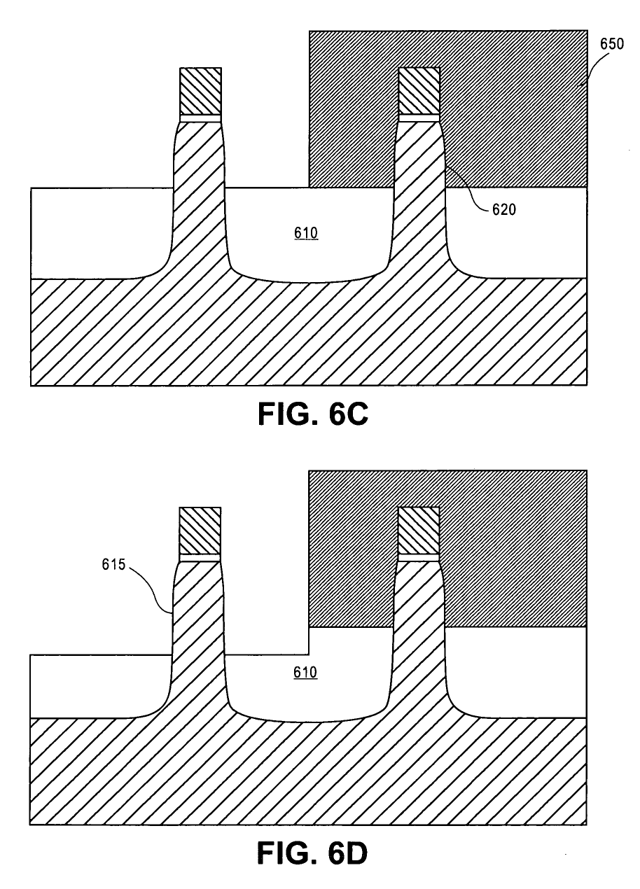

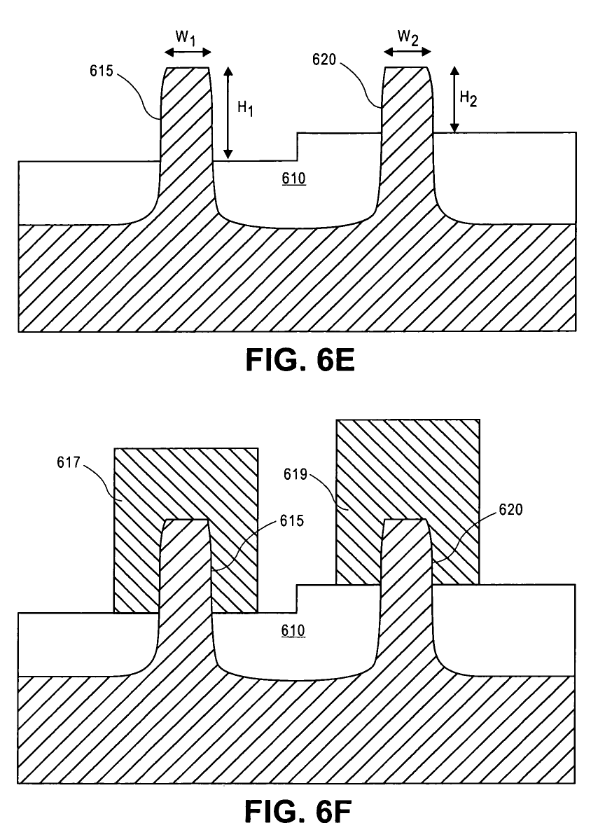

A method of fabricating a multi-gate SRAM transistor in an SRAM cell in accordance with an embodiment of the present invention, as shown in FIG. 2A and FIG. 5, is illustrated in FIGS. 6A-6F. In a particular embodiment, the fabrication begins with a “bulk” silicon monocrystalline substrate 600. In certain embodiments of the present invention, the substrate 600 is a silicon semiconductor having a doped epitaxial region with either p-type or n-type conductivity with an impurity concentration level of 1×10¹⁶-1×10¹⁹ atoms/cm³. In another embodiment of the present invention the substrate 600 is a silicon semiconductor having an undoped, or intrinsic epitaxial silicon region. In other embodiments, the bulk substrate 600 is any other well-known semiconductor material, such as gallium arsenide (GaAs), indium gallium arsenide (InGaAs), indium antimonide (InSb), gallium antimonide (GaSb), gallium phosphide (GaP), indium phosphide (InP), or carbon nanotubes (CNT).

First, a mask is used to define the non-planar semiconductor bodies of the transistors. The mask can be any well-known material suitable for defining the semiconductor substrate. In one embodiment, the mask is itself a photo-definable material. In another embodiment, the mask is formed of a dielectric material that has been lithographically defined and etched. In a particular embodiment, as shown in FIG. 6A, mask 611 is a composite stack of materials, such as a nitride 607 on an oxide 606. If mask 611 is a dielectric material, commonly known techniques, such as chemical vapor deposition (CVD), low pressure chemical vapor deposition (LPCVD), plasma enhanced chemical vapor deposition (PECVD), or even spin on processes may be used to deposit the mask material while commonly known lithography and etching process may be used to define the mask. In an embodiment of the present invention, the minimum lithographic dimension is used to define the width of mask 611. In another embodiment, the minimum width of the mask 611 is sub-lithographic, formed by commonly known techniques such as dry develop, oxidation/strip, or spacer-based processes. In a particular embodiment of the present invention, the width of mask 611 is less than 45 nanometers, and more particularly, less than 20 nanometers.

As further shown in FIG. 6A, dielectric-filled trenches form isolation 610 on substrate 600. Using commonly known techniques, a portion of the semiconductor on bulk substrate 600 is etched to form recesses or trenches on substrate 600 in alignment with mask 611. The isolation etch defining the semiconductor bodies has sufficient depth to isolate individual devices from one another and form a gate-coupled sidewall of adequate height to achieve the maximum desired channel width of the non-planar transistors. In a particular embodiment of the present invention, trenches are etched to a depth equal to the maximum desired non-planar semiconductor sidewall height plus about 100 Å to about 500 Å to accommodate a dielectric isolation. In still another embodiment, isolation trenches are etched to a depth of approximately 1500 Å to 3000 Å.

Isolation 610 is completed by filling the isolation trenches and planarizing the substrate. In an embodiment of the present invention, isolation 610 include a liner of oxide or nitride on the bottom and sidewalls of the trenches formed by commonly known methods, such as thermal oxidation or nitridation. In an alternate embodiment, no liner is employed. Next, the trenches are filled by blanket depositing an oxide by, for example, a high-density plasma (HDP) chemical vapor deposition process. The deposition process will also form dielectric on the top surfaces of the mask 611. The fill dielectric layer can then be removed from the top of mask 611 by chemical, mechanical, or electrochemical, polishing techniques. The polishing is continued until the mask 611 is revealed, forming isolation 610, as shown in FIG. 6A. In a particular embodiment of the present invention, commonly known methods are used to selectively remove the mask 611. In another embodiment, as shown in FIG. 6A, at least a portion of mask 611 is retained.

If desired, wells can then be selectively formed for pMOS and nMOS transistors (not shown). Wells can be formed using any commonly known technique to dope the semiconductor between isolation 610 to a desired impurity concentration. In embodiments of the present invention, non-planar semiconductor bodies are selectively doped to p-type or n-type conductivity with a concentration level of about 1×10¹⁶-1×10¹⁹ atoms/cm³ using commonly known masking and ion implantation techniques. In a particular embodiment, the well regions extend into the semiconductor about 500 Å deeper than isolation 610.

Next, isolation is etched back, or recessed, to expose the sidewall height H₂ of the semiconductor. As shown in FIG. 6B, isolation 610 is etched back without significantly etching the semiconductor, exposing at least a portion of semiconductor sidewalls to form non-planar semiconductor bodies 615 and 620. Any etch with good uniformity and etch rate control may be employed. In embodiments where semiconductor bodies are silicon, isolation 610 can be recessed with an etchant comprising a fluorine ion, such as HF. In some embodiments, isolation 610 is recessed using a commonly known anisotropic etch, such as a plasma or reactive ion etch (RIE) process using an etchant gas such as, but not limited to, hexafluorethane (C₂F₆). In a further embodiment, an anisotropic etch can be followed by an isotropic etch, such as a commonly known dry process using a gas such as nitrogen trifluoride (NF₃), or a wet chemical etch such as hydrofluoric acid (HF), to completely remove isolation 610 from at least a portion of the semiconductor sidewalls. Alternatively, only a portion of the unprotected isolation 610 is removed during the recess etch. In one such embodiment (not pictured), the recess etch is selective to the isolation liner material over the isolation fill material, such that the isolation recess etch is deeper along the liner region immediately adjacent to the semiconductor body than in the isolation fill region. In this manner, the width of the recess etch can then be very tightly controlled by the width of the liner, enabling a high transistor packing density.

Isolation 610 can then be selectively protected with a masking material to allow further selective definition of particular non-planar semiconductor bodies. In an embodiment, as shown in FIG. 6C, mask 750 is formed in a manner similar to that described above with reference to FIG. 6A. Mask 650 can be either a photo-definable material or a commonly known “hard” mask material that was patterned with common lithography and etch techniques. In the embodiment depicted in FIG. 6C, mask 650 is a photo-definable material (i.e. a photo resist). As shown in FIG. 6C, mask 650 is used to protect isolation 610 bordering non-planar semiconductor body 620.

Then, as shown in FIG. 6D, isolation 610 is selectively recessed by an additional amount which, when added to the amount of unselective recess etching performed in operation 6B, achieves the desired final sidewall height of non-planar semiconductor body 615. Thus, a transistor's final gate-coupled sidewall height is determined by the cumulative amount, or depth, the adjacent isolation 610 is recessed. Generally, the cumulative isolation recess depth is limited by the demands of device isolation and moderate aspect ratios. For example, subsequent processing can result in inadvertent spacer artifacts if the isolation recess produces aspects ratios that are too aggressive. In an embodiment, the selective recess of isolation 610 is performed on non-planar semiconductor body 615 that will subsequently become a multi-gate SRAM transistor, while the non-planar semiconductor body that will subsequently become a multi-gate logic transistor is masked during the selective recess of isolation 610. In yet another embodiment, a portion of isolation 610 adjacent to an SRAM transistor is recessed so that the final thickness of isolation 610 adjacent to non-planar semiconductor body 615 is about 200 Å to about 300 Å to form a SRAM transistor while the final thickness of isolation 610 adjacent to the non-planar semiconductor body protected by mask 650 is significantly more than about 300 Å to form a logic transistor.

Next, as shown in FIG. 6E, the mask 650 is then removed by commonly known means. As shown, non-planar semiconductor body 615 has a width W₁ and a sidewall height of H₁ while non-planar semiconductor body 620 has a width W₂ and H₂. In an embodiment, isolation 610 is unselectively recessed by approximately the same amount as the width W₂ of the non-planar semiconductor body 620 to form a multi-gate logic transistor wherein H₂ is equal to W₂, while isolation 610 is selectively recessed by an additional amount so that the sidewall height H₁ is significantly larger than width W₁ of non-planar semiconductor body 615 to form a multi-gate SRAM transistor. In another embodiment, the selective STI recess etch exposes at least 25% more sidewall height than exposed by the non-selective STI recess etch in a non-planar semiconductor body that will subsequently become a multi-gate SRAM transistor. It should be appreciated that the process of selectively masking a portion of the isolation 610 and recess etching the isolation 610 by a specific amount can be repeated a number of times and in a number of ways to achieve a menu of gate-coupled surface perimeters, corresponding to a menu of non-planar transistor channel widths for various SRAM and logic transistors, in accordance with the present invention.

Once the selective isolation recess etches are completed, all isolation masks are removed with commonly known techniques. If desired, a final clean, such as hydrofluoric acid (HF), may then be performed on all non-planar semiconductor bodies, further recessing all isolation regions. In a particular embodiment of the present invention, additional sacrificial oxidation and blanket oxide etches or cleans are performed to both improve the semiconductor surface quality and further tailor the shape of the semiconductor bodies through corner rounding, feature shrinking, etc.

Gate stacks can then be formed over the semiconductor bodies in a manner dependent on the type of non-planar device (dual-gate, tri-gate, etc.) and/or the conductivity type of the transistor. In a tri-gate embodiment of the present invention, as shown in FIG. 6F, gate stacks 617 and 619 are formed on the top surface, as well as on, or adjacent to, the exposed sidewalls of the non-planar semiconductor bodies 615 and 620, respectively. In certain other embodiments, such as dual-gate embodiments, the gate stack is not formed on the top surfaces of the non-planar semiconductor bodies. Gate stacks 617 and 619 may be formed by commonly-known techniques, such as blanket depositing a gate electrode material over the substrate and then patterning the gate electrode material. In other embodiments of the present invention, the gate electrode is formed using “replacement gate” methods. In such embodiments, the gate electrode utilizes a fill and polish technique similar to those commonly employed in damascene metallization technology, whereby the recessed isolation may be completely filled with gate electrode material.

Gate stacks 617 and 619 can include a deposited dielectric or a grown dielectric and a gate electrode. In an embodiment of the present invention, the gate dielectric layer is a silicon dioxide dielectric film grown with a dry/wet oxidation process. In an embodiment of the present invention, the gate dielectric is a deposited high dielectric constant (high-K) metal oxide dielectric, such as, but not limited to, tantalum pentaoxide, titanium oxide, hafnium oxide, zirconium oxide, aluminum oxide, or another high-K dielectric, such as barium strontium titanate (BST). A high-K film can be formed by well-known techniques, such as chemical vapor deposition (CVD) and atomic layer deposition (ALD).

In some embodiments of the present invention, gate stacks 617 and 619 further include gate electrodes comprising metals such as, but not limited to, tungsten, tantalum nitride, titanium nitride or titanium silicide, nickel silicide, or cobalt silicide. In still other embodiments, the gate electrode comprises silicides.

Source/drain regions (not shown) are then formed in the non-planar semiconductor bodies 615 and 620 on opposite sides of gate stacks 617 and 619. For a pMOS transistor, the semiconductor body is doped to p-type conductivity and to a concentration of 1×10¹⁹-1×10²¹ atoms/cm³. For an nMOS transistor, the semiconductor body is doped with n-type conductivity ions to a concentration of 1×10¹⁹-1×10²¹ atoms/cm³. At this point the CMOS transistor of the present invention is substantially complete and only device interconnection remains.

Although the present invention has been described in language specific to structural and/or methodological acts, it is to be understood that the invention defined in the d claims is not necessarily limited to the specific features or acts described. The specific and acts disclosed are instead to be understood as particularly graceful implementations aimed invention useful for illustrating the present invention.

What is claimed is:

1. An apparatus comprising:
a first multi-gate transistor having a non-planar semiconductor body with first sidewall height; and
a second multi-gate transistor having a non-planar semiconductor body with a second sidewall height, wherein the first multi-gate transistor is in an SRAM cell of a microprocessor.

2. The apparatus of claim 1, wherein the first non-planar semiconductor body sidewall height is greater than the second non-planar semiconductor body sidewall height.

3. The apparatus of claim 2, wherein the second multi-gate transistor is in the SRAM cell.

4. The apparatus of claim 3, wherein the first multi-gate transistor is a pull-down transistor and the second multi-gate transistor is a pass transistor.

5. The apparatus device of claim 4, wherein the first non-planar semiconductor body sidewall height is greater than the second non-planar semiconductor body sidewall height by an amount sufficient to make the channel width of the pull down transistor 1.5 times greater than the channel width of the pass transistor when the first and second non-planar semiconductor bodies have the same top surface width.

6. The apparatus of claim 3, wherein the first multi-gate SRAM transistor and the second multi-gate SRAM transistor are formed from one continuous non-planar semiconductor body having a first region with the first sidewall height adjacent to a second region of the non-planar semiconductor body having the second sidewall height.

7. The apparatus of claim 1, wherein the first and second multi-gate transistors are tri-gate transistors having a channel width equal to the non-planar semiconductor body width added to twice the sidewall height of the non-planar semiconductor body.

8. The apparatus of claim 7, wherein the first multi-gate transistor has a non-planar semiconductor body top surface width which is equal to the non-planar semiconductor body top surface width of the second multi-gate transistor.

9. An apparatus comprising:
a multi-gate SRAM transistor in an integrated circuit having a first non-planar semiconductor body sidewall height and a first non-planar semiconductor body width; and
a multi-gate logic transistor in the integrated circuit having a second non-planar semiconductor body sidewall height and a second width; and, wherein the first non-planar semiconductor body sidewall height is greater than the second non-planar semiconductor body sidewall height.

10. The apparatus of claim 9, wherein the multi-gate SRAM transistor has a channel width 1.5 times greater than that of the multi-gate logic transistor and the first non-planar semiconductor body width is equal to the second non-planar semiconductor body width.

11. The apparatus of claim 9, wherein the first non-planar semiconductor body width is between 20% and 35% greater than the second non-planar semiconductor body width.

12. The apparatus of claim 9, wherein the first non-planar semiconductor body sidewall height is between 50% and 100% greater than the second non-planar semiconductor body sidewall height.

13. A method of forming a multi-gate SRAM transistor comprising:
forming first isolation region on a bulk semiconductor substrate adjacent to and planar with a pull-down SRAM transistor semiconductor body;
forming a second isolation region on the bulk semiconductor substrate adjacent to and planar with a second semiconductor body;
performing a first etch on both the first isolation region and the second isolation region to expose at least a portion of the sidewalls of both the SRAM transistor semiconductor body and the second transistor semiconductor body;
masking the second isolation region;
performing a second etch on the first isolation region to expose an additional portion of the SRAM transistor semiconductor body sidewalls;
forming a first gate insulator adjacent to the exposed portion of the sidewalls of the pull-down SRAM transistor semiconductor body and forming a second gate insulator adjacent to the exposed portion of the sidewalls of the second transistor semiconductor body;
forming a first gate electrode adjacent to the first gate insulator and forming a second gate electrode adjacent to the second gate insulator; and
forming a first pair of source/drain regions on opposite sides of the first gate electrode and a second pair of source/drain regions on opposite sides of the second gate electrode.

14. The method of claim 13 further comprising:
forming a first gate insulator and first gate electrode on a top surface of the pull-down SRAM transistor semiconductor body to form a tri-gate device; and
forming a second gate insulator and second gate electrode on a top surface of the second transistor semiconductor body to form a tri-gate device.

15. The method of claim 13, wherein the second transistor is a pass transistor in an SRAM cell of a microprocessor.

16. The method of claim 15, wherein the second etch exposes approximately 25% more sidewall than the first etch.

17. The method of claim 13, wherein the second transistor is a logic transistor in a core of a microprocessor.

18. The method of claim 17, wherein the second etch exposes between 50% and 100% more sidewall than the first etch.

19. The method of claim 13, wherein the both the first and second etches are wet chemical etches.

20. The method of claim 19, wherein the wet chemical etches comprises HF.
